(19) United States
(12) Patent Application Publication
(10) Pub. No.: US 2020/0106426 A1
(43) Pub. Date: Apr. 2, 2020

(54) AREA EFFICIENT FLOP FOR USAGE IN SDB BASED LIBRARIES AND LOW VOLTAGE APPLICATIONS

(71) Applicant: Samsung Electronics Co., Ltd., Suwon-si (KR)

(72) Inventor: Vasisht M. VADI, San Diego, CA (US)

(21) Appl. No.: 16/372,398

(22) Filed: Apr. 1, 2019

Related U.S. Application Data
(60) Provisional application No. 62/739,799, filed on Oct. 1, 2018.

(51) Int. Cl. H03K 3/037

(52) U.S. Cl. CPC H03K 3/0372; H03K 19/20

(57) ABSTRACT

A flip-flop includes a gate circuit and five logic gates. The gate circuit receives as inputs a data input d, an intermediate signal p, a control signal si and a control signal se, and outputs an intermediate signal pb. A first logic gate receives as inputs the intermediate signal pb, an intermediate signal cb, and outputs an intermediate signal c. A second logic gate receives as inputs a clock signal clk and the intermediate signal c, and outputs the intermediate signal cb. The third logic gate receives as inputs the clock signal clk, the intermediate signal p, the intermediate signal cb, and outputs the intermediate signal p. The fourth logic gate receives as inputs the intermediate signal cb and a signal qb, and outputs a signal q. The fifth logic gate receives as inputs the intermediate signal p and first signal q, and outputs the signal qb.

### CROSS-REFERENCE TO RELATED APPLICATION

This patent application claims the priority benefit under 35 U.S.C. § 119(e) of U.S. Provisional Patent Application No. 62/739,799, filed on Oct. 1, 2018, the disclosure of which is incorporated herein by reference in its entirety.

### TECHNICAL FIELD

The subject matter disclosed herein generally relates to semiconductor devices. More specifically, the subject matter disclosed herein relates to a flip-flop circuit and layout that optimizes the amount of space (area) used when the flip-flop is laid out on a single diffusion break (SDB) technology.

### BACKGROUND

As technology nodes shrink, it is becoming harder and harder to shrink the area of a semiconductor device, such as a flip-flop. Flip-flop area scaling may be a key metric for new technology nodes in terms of area and number of contacted poly pitches (CPP) used to build a fabricated flip-flop.

### SUMMARY

An example embodiment provides a flip-flop that may include a pair of primary latches and a secondary latch configured to output a first signal q and a second signal qb that is an inverse of the first signal q. The pair of primary latches may include a gate circuit, a first logic gate, a second logic gate and a third logic gate. The secondary latch may include a fourth logic gate and a fifth logic gate. The gate circuit may be configured to receive as inputs a data signal d, a first intermediate signal p, a first control signal si and a second control signal se, and to output a second intermediate signal pb. The first logic gate may be configured to receive as an input the second intermediate signal pb, a third intermediate signal cb, and to output a fourth intermediate signal c. The second logic gate may be configured to receive as inputs a clock signal clk and the fourth intermediate signal c, and to output the third intermediate signal cb. The third logic gate may be configured to receive as inputs the clock signal clk, the second intermediate signal pb and the third intermediate signal cb, and to output the first intermediate signal p. The fourth logic gate may be configured to receive as inputs the third intermediate signal cb and the second signal qb, and to output the first signal q. The fifth logic gate may be configured to receive as inputs the first intermediate signal p and the first signal q, and to output the second signal qb.

Another example embodiment provides an apparatus that may include a flip-flop arranged on a single diffusion break substrate, a double diffusion break substrate, or an alternative diffusion break substrate. The flip-flop may include a pair of primary latches and a secondary latch configured to output a first signal q and a second signal qb that is an inverse of the first signal q. The pair of primary latches may include a gate circuit, a first logic gate, a second logic gate and a third logic gate. The secondary latch may include a fourth logic gate and a fifth logic gate. The gate circuit may be configured to receive as inputs a data signal d, a first intermediate signal p, a first control signal si and a second control signal se, and to output a second intermediate signal pb. The first logic gate may be configured to receive as an input the second intermediate signal pb, a third intermediate signal cb, and to output a fourth intermediate signal c. The second logic gate may be configured to receive as inputs a clock signal clk and the fourth intermediate signal c, and to output the third intermediate signal cb. The third logic gate may be configured to receive as inputs the clock signal clk, the second intermediate signal pb and the third intermediate signal cb, and to output the first intermediate signal p. The fourth logic gate may be configured to receive as inputs the third intermediate signal cb and the second signal qb, and to output the first signal q. The fifth logic gate may be configured to receive as inputs the first intermediate signal p and the first signal q, and to output the second signal qb.

Still another example embodiment provides a flip-flop that may include a gate circuit, a first logic circuit, a second logic circuit, a third logic circuit, a fourth logic circuit and a fifth logic circuit. The gate circuit may be configured to receive as inputs a data input signal d, a first intermediate signal p, a first control signal si and a second control signal se, and to output a second intermediate signal pb. The first logic gate may be configured to receive as an input the second intermediate signal pb, a third intermediate signal cb, and to output a fourth intermediate signal c. The second logic gate may be configured to receive as inputs a clock signal clk and the fourth intermediate signal c, and to output the third intermediate signal cb. The third logic gate may be configured to receive as inputs the clock signal clk, the second intermediate signal p, the third intermediate signal cb, and to output the first intermediate signal p. The fourth logic gate may be configured to receive as inputs the third intermediate signal cb and a second signal qb, and to output a first signal q. The fifth logic gate may be configured to receive as inputs the first intermediate signal p and the first signal q, and to output the second signal qb.

### BRIEF DESCRIPTION OF THE DRAWINGS

In the following section, the aspects of the subject matter disclosed herein will be described with reference to exemplary embodiments illustrated in the figures, in which:

FIG. 1A is a schematic diagram for an embodiment of a flip-flop that is based on transmission gate logic;

FIG. 1B is a schematic diagram of a NAND-based flip-flop;

FIG. 1C is a schematic diagram of a NOR-based flip-flop;

FIG. 2A is a schematic diagram of an example embodiment of a flip-flop according to the subject matter disclosed herein;

FIG. 2B is a schematic diagram of the input gate circuit according to the subject matter disclosed herein;

FIG. 2C shows a truth table for the intermediate signal pb provided by the input gate circuit as a function of the data input signal d, the intermediate signal p, the scan input signal si and the scan enable signal se;

FIGS. 3A and 3B respectively depict example transistor arrangements of the input gate circuit of FIG. 2A on an SDB substrate according to the subject matter disclosed herein;

FIG. 4 is a schematic diagram of an example embodiment of a flip-flop that includes an input signal setb according to the subject matter disclosed herein;

FIG. 5 is a schematic diagram of an example embodiment of a flip-flop that includes an input signal resetb according to the subject matter disclosed herein;

FIG. 6 is a schematic diagram of an example embodiment of a flip-flop that includes an input signal set and an input signal reset according to the subject matter disclosed herein;

FIG. 7A is a schematic diagram of an example embodiment of a flip-flop according to the subject matter disclosed herein;

FIG. 7B is a schematic diagram of the gate circuit according to the subject matter disclosed herein;

FIG. 8 is a schematic diagram of an example embodiment of a flip-flop that includes an input signal set according to the subject matter disclosed herein; and

FIG. 9 is a schematic diagram of an example embodiment of a flip-flop that includes an input signal set and an input signal reset according to the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail not to obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing particular exemplary embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement the teachings of particular embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

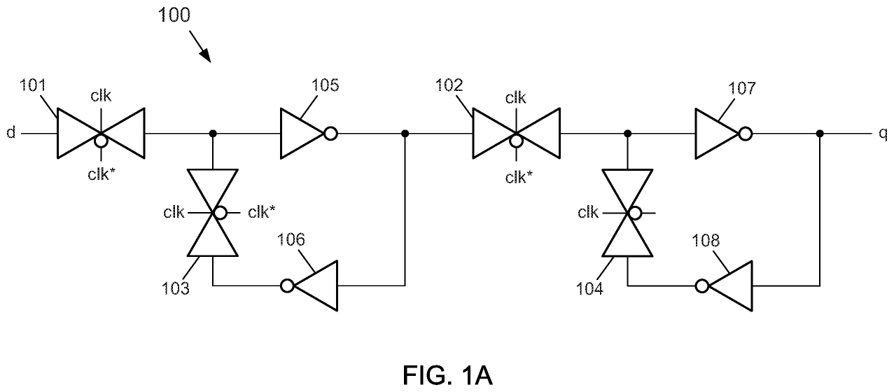

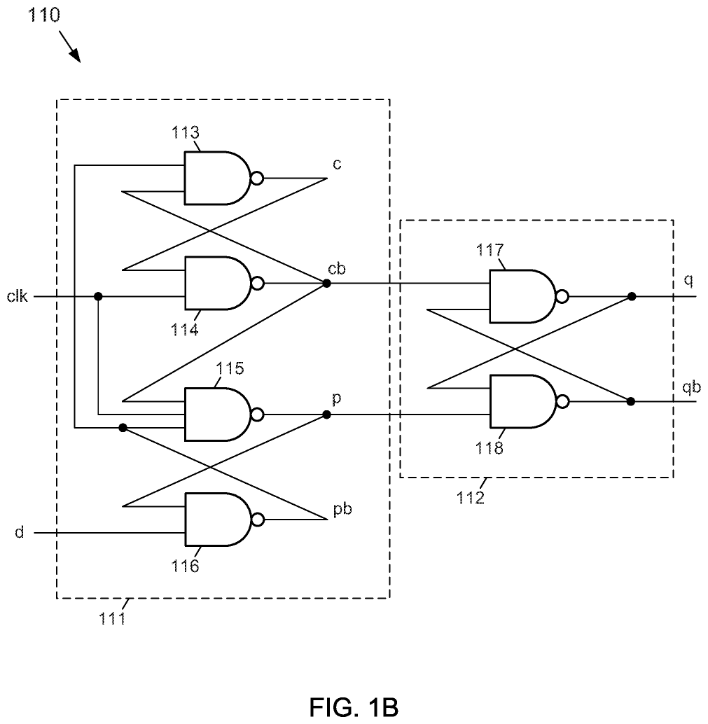

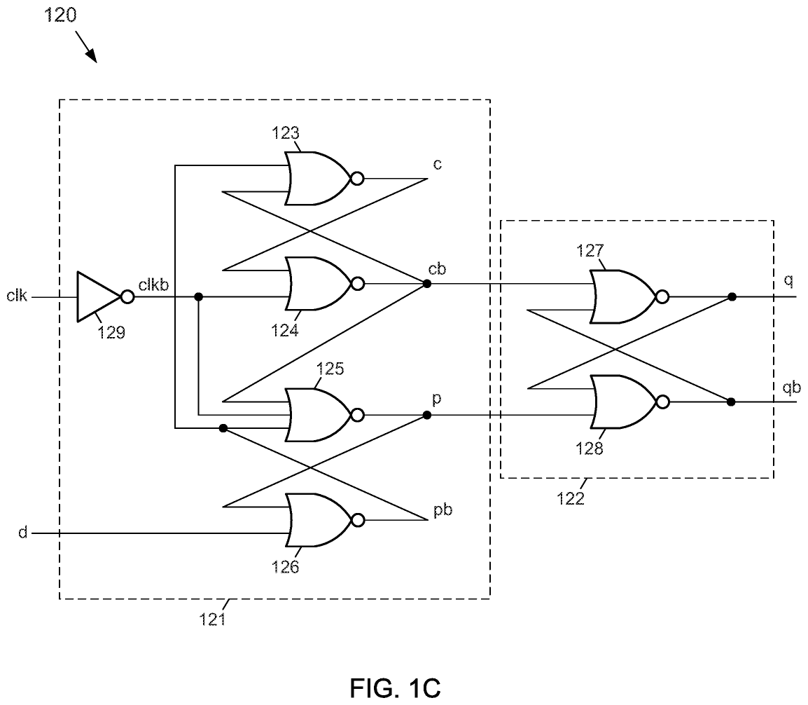

The subject matter discloses herein relates to a flip-flop architecture having an optimized schematic and layout that saves space (area) and power when fabricated on a single diffusion break (SDB) standard-cell substrate. The flip-flop architecture may also be fabricated on double diffusion break (DDB), multi-diffusion break (MDB) and/or alternative diffusion break (ADB) substrates. The flip-flop architecture provides both NAND-based flip-flops and NOR-based flip-flops, and both types of flip-flops output both q and qb output signals. Both types of flip-flops use full complementary metal-oxide-semiconductor (CMOS) logic so both types of flip-flops may be used for low-voltage (LV) applications. This is in contrast to transmission-gate-type flip-flops, such as depicted in FIG. 1A, which may have circuit limitations at low voltages. Usage of regular NAND gates may also be better for yield and process uniformity. Additionally, the layout may be optimized to reduce the CPP number, reduce the number of blocked metal tracks, and reduce internal capacitance on clock and other internal signal nodes.

In one embodiment, a flip-flop may include a scan-optimized input gate that saves one CPP of area and if fabricated on an SDB substrate optimizes the area used by the flip-flop in terms of CPP units. Although SDB provides an area efficiency for the subject matter disclosed herein, the flip-flop circuit configuration disclosed herein may also be fabricated on a DDB, an MDB and/or an ADB substrates for the number of diffusion breaks that may be left between transistors. Additionally, in one embodiment, a flip-flop may provide an efficient implementation of resetb and setb input signals, so a circuit design may take advantage of a negative polarity of set and reset input signal, thereby further saving space. Additional embodiments of flip-flops may be generated by 1) switching the q and qb signal designation, thereby inverting the input polarity of d and changing a set signal to be a reset signal and changing a reset signal to be a set signal; 2) bubble pushing to convert a flip-flop from a NAND-based topology to a NOR-based topology; 3) inverters and/or buffers may be inserted on input and/or output signals to obtain a desired polarity or output drive strengths; and 4) the q and/or the qb output may be tapped depending upon application needs. These techniques may help generate an optimized area efficient layout for a full family of flip-flops and different possible embodiments.

FIG. 1A is a schematic diagram for an embodiment of a flip-flop 100 that is based on transmission gate logic. Either a tristate inverter or a transmission-gate arrangement may be used for this flip-flop embodiment. The flip-flop 100 receives a data input signal d and generates an output signal q, and includes four transmission gates 101-104 and four inverters 105-108. The input signal d is applied to the first transmission gate 101. An output of the transmission gate 101 is applied to an input of an inverter 105. The output of the inverter 105 is input to a transmission gate 102 and an input of an inverter 106. The output of the inverter 106 is input to a transmission gate 103, and the output of the transmission gate 103 is input to the input of the inverter 105. The output of the transmission gate 102 is input to an inverter 107. The output of the inverter 107 is input to an input of an inverter 108. The output of the inverter 108 is input to a transmission gate 104, and the output of the transmission gate 104 is input to the input of the inverter 107. The output signal q of the flip-flop 100 is generated by the inverter 107. In an alternative embodiment, a tristate inverter may be used instead of transmission-gates, which makes the design more robust for lower voltages, but may have the drawback of using a larger area. Depending on how much area is needed to implement the cross-couple in a flip-flop, versions of the flip-flop 100 may be inefficient in area and/or power consumption in comparison to the subject matter disclosed herein.

FIG. 1B is a schematic diagram of a NAND-based flip-flop 110. The flip-flop 110 receives a data input signal d and a clock signal clk, and generates output signals q and qb. The output signal qb is an inverted signal of the output signal q. The flip-flop 100 of FIG. 1A includes two latches, whereas the flip-flop 110 of FIG. 1B includes three latches. That is, the flip-flop 110 includes three latches in total as a pair of primary latches 111 (one latch for a clock input and one latch for a data input), and a secondary latch 112 in which the primary latches 111 have unidirectional control over the secondary latch 112. The primary latches 111 include NAND gates 113-116, and the secondary latch 112 includes NAND gates 117 and 118.

The NAND gate 113 receives as inputs an intermediate signal pb, an intermediate signal cb, and outputs an intermediate signal c. The NAND gate 114 receives as inputs the clock signal clk and the intermediate signal c, and outputs the intermediate signal cb. The NAND gate 115 receives as inputs the clock signal clk, the intermediate signal pb and the intermediate signal cb, and outputs the intermediate signal p. The NAND gate 116 receives as inputs the data input signal d and the intermediate signal p, and outputs the intermediate signal pb. The signal names p, pb, c and cb for the flip-flop 100 and for other flip-flops disclosed herein have been arbitrarily selected for the internal signals of the corresponding flip-flop. Additionally, the internal signals for the flip-flop 100 and other flip-flops described herein are not inverses of each other in all operating modes.

The NAND gate 117 receives as inputs the intermediate signal cb and an output signal qb, and outputs the output signal q. The NAND gate 118 receives as inputs the output signal q and the intermediate signal p, and outputs the output signal qb.

FIG. 1C is a schematic diagram of a NOR-based flip-flop 120. The flip-flop 120 receives a data input signal d and a clock signal clk, and generates output signals q and qb. Output signal qb is an inverted signal of the output signal q. Similar to the flip-flop 100 of FIG. 1, the flip-flop 120 includes three total latches as a primary pair of latches 121 for a clock input and a data input, and a secondary latch 122. The primary latch 121 has unidirectional control over the secondary latch 112. The two primary latches 121 include NOR gates 123-126, and the secondary latch 122 includes NOR gates 127 and 128. The flip-flop 120 also includes an inverter 129.

The NOR gate 123 receives as inputs an intermediate signal pb, an intermediate signal cb, and outputs an intermediate signal c. The NOR gate 124 receives as inputs an inverted clock signal clkb and the intermediate signal c, and outputs the intermediate signal cb. The NOR gate 125 receives as inputs the inverted clock signal clkb, the intermediate signal pb and the intermediate signal cb, and outputs the intermediate signal p. The NOR gate 126 receives as inputs the data input signal d and the intermediate signal p, and outputs the intermediate signal pb.

The NOR gate 127 receives as inputs the intermediate signal cb and the output signal qb, and outputs the output signal q. The NOR gate 118 receives as inputs the output signal q and the intermediate signal p, and outputs the output signal qb.

It is important that the cross-couple layout of the transmission gates of the flip-flop 100 be efficient so that the flip-flop occupies as small an area as possible. In some embodiments of the flip-flops, tristate inverters are used to replace the transmission gates to provide a full-CMOS, low-voltage operation. Such tristate-inverter-based flip-flops, however, involve more transistors than transmission-gate-based flip-flops and, therefore, occupy a greater area than the transmission-gate-based flip-flops.

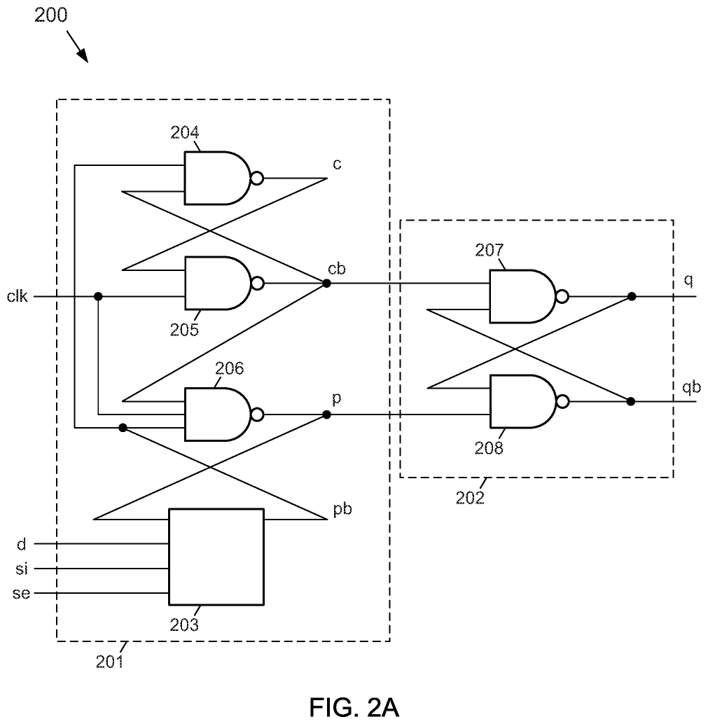

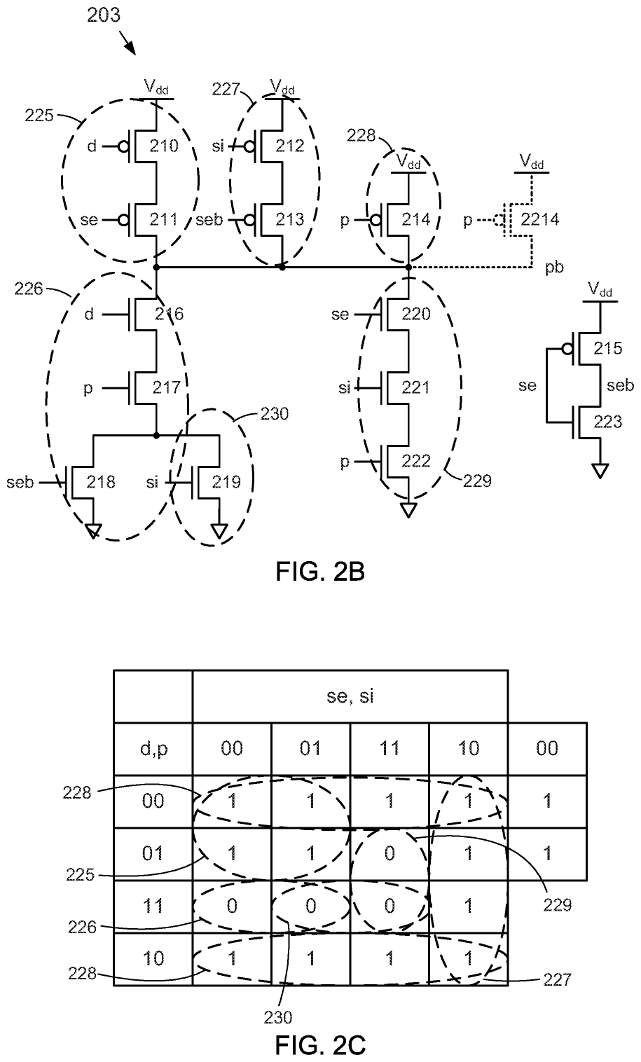

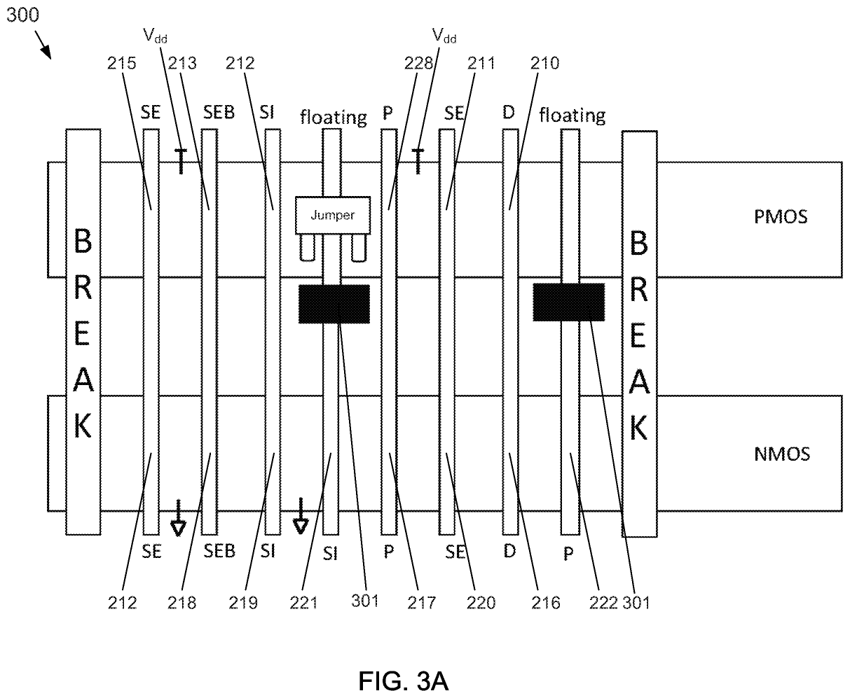

FIG. 2A is a schematic diagram of an example embodiment of a flip-flop 200 according to the subject matter disclosed herein. The flip-flop 200 may receive a data input signal d, a clock signal clk, a scan input signal si and a scan enable signal se, and generates output signals q and qb. The flip-flop 200 may include a pair of primary latches 201 for the clock signal clk and the data input d, and a secondary latch 202. The primary pair of latches 201 may have unidirectional control over the secondary latch 202. The primary pair of latches 201 may include an input gate circuit 203 and NAND gates 204-206, and the secondary latch 202 may include NAND gates 207 and 208.

The input gate circuit 203 may receive as inputs the data input d, the scan input signal si, the scan enable signal se and an intermediate signal p, and outputs an intermediate signal pb. The NAND gate 204 may receive as inputs the intermediate signal pb, an intermediate signal cb, and outputs an intermediate signal c. The NAND gate 205 may receive as inputs the clock signal clk and the intermediate signal c, and outputs the intermediate signal cb. The NAND gate 206 may receive as inputs the clock signal clk, the intermediate signal pb and the intermediate signal cb, and outputs the intermediate signal p.

The NAND gate 207 may receive as inputs the intermediate signal cb and the output signal q, and outputs the output signal q. The NAND gate 208 may receive as inputs the output signal q and the intermediate signal p, and outputs the output signal qb.

FIG. 2B is a schematic diagram of the input gate circuit 203 according to the subject matter disclosed herein. The gate circuit 203 may include PMOS transistors 210-215, and NMOS transistors 217-223. The gate circuit 203 performs the function of a scan multiplexer. For example, an inverting multiplexing gate between the data input d and the scan input signal si that is controlled by the scan enable signal se may be combined with a subsequent NAND gate. There would be, however, an extra inversion on the data path when compared to the gate circuit 203 if this is done. Merging the logic function into the gate circuit 203 removes an inversion and may be implemented in minimal area. To provide a full standard cell library that includes all family of flip-flops and all variations of flip-flops and signal polarities used by designers, it may be useful to have available both the configuration of the gate circuit 203 and a configuration of an inverting multiplexing gate with a subsequent NAND gate.

The PMOS transistor 210 may have a first source/drain region coupled to a Vdd power supply voltage, a second source/drain region, and a gate terminal coupled to the data input signal d. The PMOS transistor 211 may have a first source/drain region coupled to the second source/drain region of the PMOS transistor 210, a second source/drain region that outputs the intermediate signal pb, and a gate terminal coupled to the scan enable signal se. The PMOS transistor 212 may have a first source/drain region coupled to the Vdd power supply voltage, a second source/drain region, and a gate terminal coupled to the scan input signal si. The PMOS transistor 213 may have a first source/drain region coupled to the second source/drain region of the PMOS transistor 212, a second source/drain region that outputs the intermediate signal pb, and a gate terminal coupled to a signal seb, which is an inversion of the scan enable signal se. The PMOS transistor 214 may have a first source/drain region coupled to the Vdd power supply voltage, a second source/drain region that outputs the intermediate signal pb, and a gate terminal coupled to the intermediate signal p. The PMOS transistor 215 may include a first source/drain region coupled to the Vdd power supply voltage, a second source/drain region to output the signal seb, and a gate terminal coupled to the scan enable signal se. A PMOS transistor 2214 indicated by a dashed line may be connected in the same way as the PMOS transistor 214; however, the PMOS transistor 2214 may be redundant and, therefore, optional. Choice of using the PMOS transistor 2214 may be based on layout efficiency. The PMOS transistor 2214 may not be needed for circuit operation. To reduce capacitance and power inside the flip-flop 200, the PMOS transistor 2214 may be replaced with a dummy transistor.

The NMOS transistor 216 may include a first source/drain region that outputs the intermediate signal pb, a second source/drain region, and a gate terminal coupled to the data input signal d. The NMOS transistor 217 may include a first source/drain region coupled to the second source/drain region of the NMOS transistor 216, a second source/drain region, and a gate terminal coupled to the intermediate signal p. The NMOS transistor 218 may include a first source/drain region coupled to the second source/drain region of the NMOS transistor 217, a second source/drain region coupled to ground, and a gate terminal coupled to the signal seb. The NMOS transistor 219 may include a first source/drain region coupled to the second source/drain region of the NMOS transistor 217, a second source/drain region coupled to ground, and a gate terminal coupled to the scan input signal si. The NMOS transistor 220 may include a first source/drain region to output the intermediate signal pb, a second source/drain region, and a gate terminal coupled to the scan enable signal se. The NMOS transistor 221 may include a first source/drain region coupled to the second source/drain region of the NMOS transistor 220, a second source/drain region, and a gate terminal coupled to the scan input signal si. The NMOS transistor 222 may include a first source/drain region coupled to the second source/drain region of the NMOS transistor 221, a second source/drain region coupled to ground, and a gate terminal coupled to the intermediate signal p. The NMOS transistor 223 may include a first source/drain region coupled to the second source/drain region of the PMOS transistor 215, a second source/drain region coupled to ground, and a gate terminal coupled to the scan enable signal se.

FIG. 2C shows a truth table for the intermediate signal pb provided by the input gate circuit 203 as a function of the data input signal d, the intermediate signal p, the scan input signal si and the scan enable signal se. The portion of the truth table indicated by 225 is provided by the portion of the input gate circuit 203 indicated at 225 in FIG. 2B. The portion 226 is provided by the portion of the input gate circuit 203 indicated at 226. The portion 227 is provided by the portion of the input gate circuit 203 indicated at 227. The portion 228 (two places) is provided by the portion of the input gate circuit 203 indicated at 208. The portion 229 is provided by the portion of the input gate circuit 203 at 229, and the portion 230 is provided by the portion of the input gate circuit 203 at 230.

It should be noted that if there is no risk of a glitch occurring in the intermediate signal pb if the scan signal si equals the data input d and the signal seb changes, then the portion 230 (i.e., NMOS transistor 219) of the input gate circuit 203 may be omitted. For most flip-flop circuits and designs disclosed herein, it is a good, very low risk assumption that that scan signal si and the scan enable signal se changing at the same time causes a glitch, so the input NMOS transistor 219 may often be omitted and replaced by a dummy or floating gate depending on the preference of a layout designer.

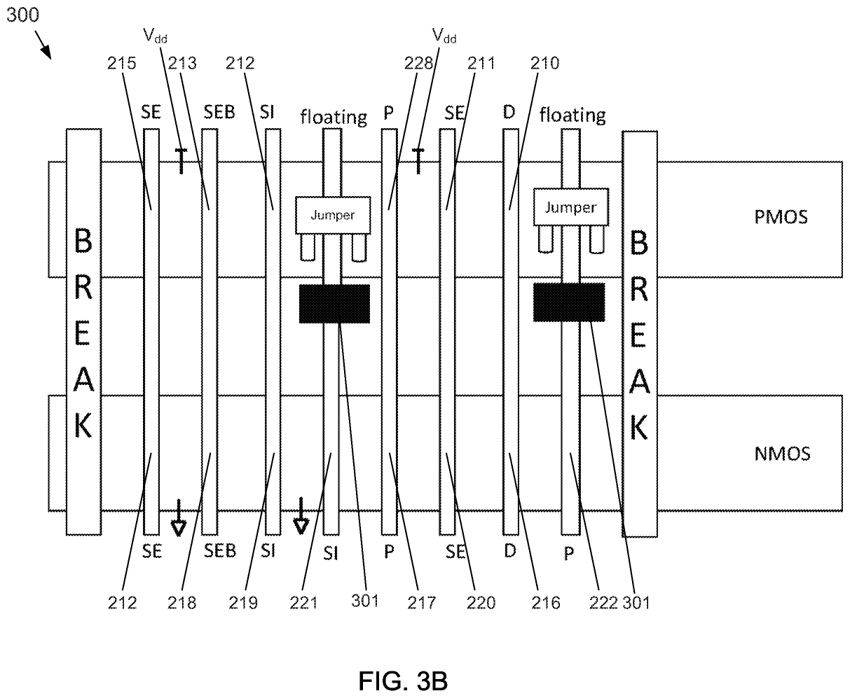

FIGS. 3A and 3B respectively depict example transistor arrangements 300 and 301 of the input gate circuit 203 of FIG. 2A on an SDB substrate according to the subject matter disclosed herein. The transistors in FIG. 2B are indicated in FIGS. 3A and 3B. Additionally, in FIG. 3A, one jumper over a dummy PMOS transistor and two cuts 301 are indicated, whereas in FIG. 3B, two jumpers over dummy PMOS transistors and two cuts are indicated. The metallization for the input gate circuit is not shown in either FIG. 3A or 3B.

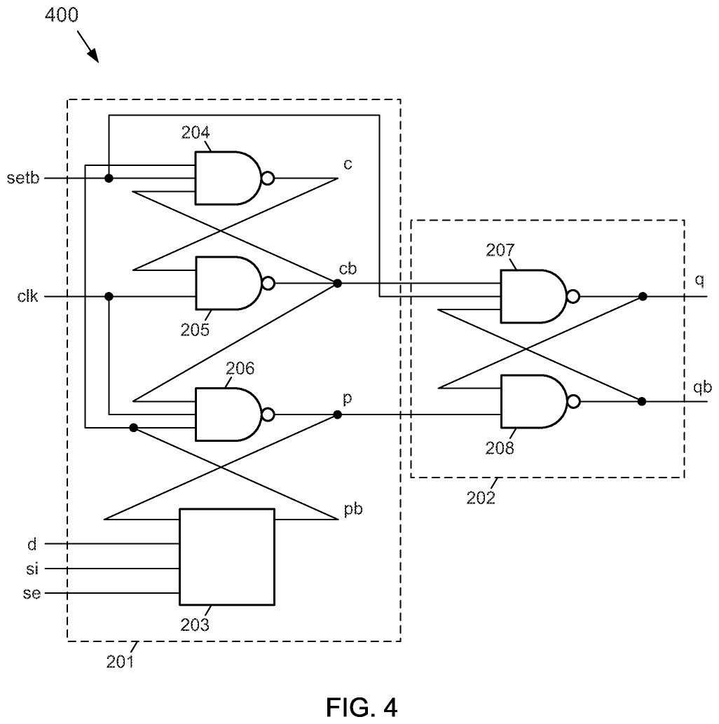

FIG. 4 is a schematic diagram of an example embodiment of a flip-flop 400 that includes an input signal setb according to the subject matter disclosed herein. The flip-flop 400 may be configured to be identical to the flip-flop 200 in FIG. 2A with the addition of an input signal setb that may be input to the NAND gate 204 and the NAND gate 207. The addition of the input signal setb may add two CPP units to the layout of the flip-flop 400.

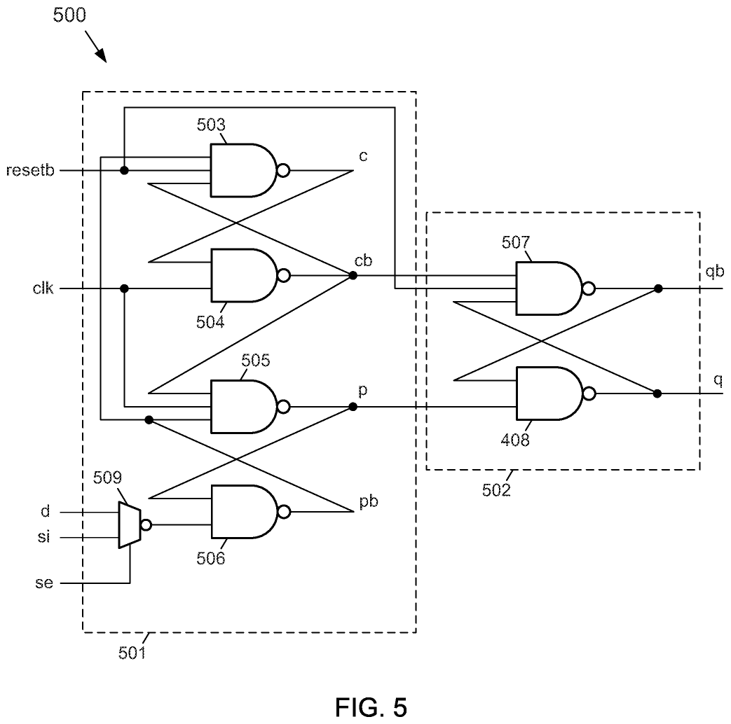

By flipping the polarity of the q and qb output signals of the flip-flop 400, the flip-flop 400 of FIG. 4 may be reconfigured to be used for a scan-in flip-flop having a resetb input signal. FIG. 5 is a schematic diagram of an example embodiment of a flip-flop 500 that includes an input signal resetb according to the subject matter disclosed herein. The flip-flop 500 may receive a data input signal d, a clock signal clk, a scan input signal si, a scan enable signal se and an inverted reset signal resetb, and generates output signals q and qb.

Similar to the flip-flops 200 and 400, the flip-flop 500 may include a primary latch pair 501 and a secondary latch 502. The primary latch pair 401 may include NAND gates 503-506, and the secondary latch 502 may include NAND gates 507 and 508.

The NAND gate 503 may receive as inputs the input signal resetb, an intermediate signal pb, an intermediate signal cb, and outputs an intermediate signal c. The NAND gate 504 may receive as inputs the clock signal clk and the intermediate signal c, and outputs the intermediate signal cb. The NAND gate 505 may receive as inputs the clock signal clk, the intermediate signal pb and the intermediate signal cb, and outputs the intermediate signal p. The NAND gate 506 may receive as inputs either an inverted data input d or an inverted scan signal si and the intermediate signal p, and outputs the intermediate signal pb. A multiplexer 509 may receive the data input signal d and the scan input signal si, and outputs an inverted version of either signal depending on whether the flip-flop is in a normal mode (data input signal d) or a scan mode (scan input signal si). The multiplexer 509 is controlled by the scan enable signal se.

The NAND gate 507 may receive as inputs the input signal resetb, the intermediate signal cb and the output signal q, and outputs the output signal qb. The NAND gate 508 may receive as inputs as inputs the output signal qb and the intermediate signal p, and outputs the output signal q.

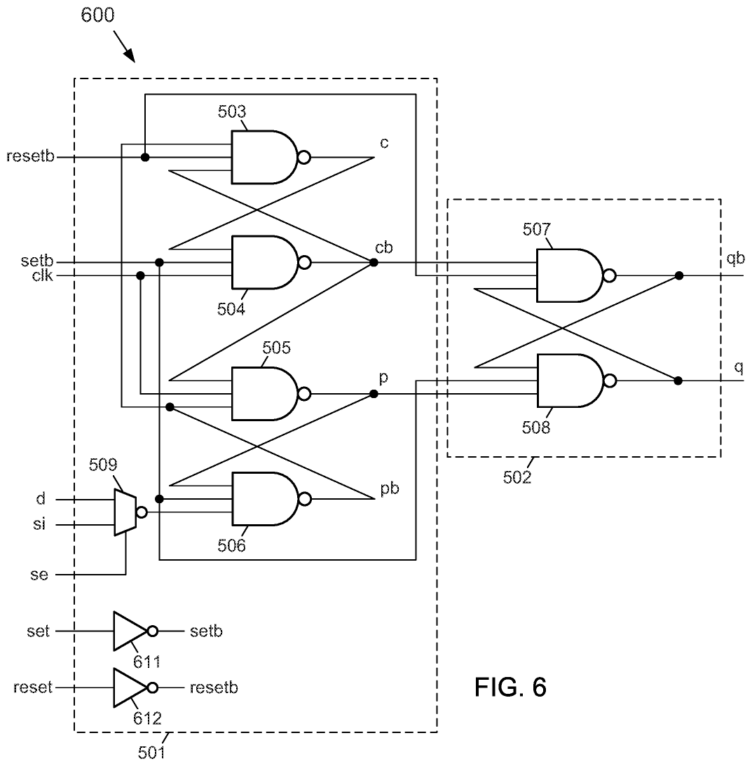

FIG. 6 is a schematic diagram of an example embodiment of a flip-flop 600 that includes an input signal set and an input signal reset according to the subject matter disclosed herein. The flip-flop 600 may be configured to be identical to the flip-flop 500 in FIG. 5 with the addition of two inverters 611 and 612. The flip-flop 600 may receive a data input signal d, a clock signal clk, a scan input signal si, a scan enable signal se, a set input signal, an inverted signal setb, a reset input signal and an inverted reset signal resetb, and generates output signals q and qb. In the flip-flop 600, either polarity of set/setb signals or reset/resetb signals may be used based on design preference.

The flip-flop shown in FIG. 6 provides a good implementation if set and reset are not asserted at the same time, or when a priority conflict is not important. Some design styles may, however, need based on RTL coding style for set to take priority when set and reset are both asserted. In such a situation, the best embodiment implementation may be to convert the input invert on the reset signal to a logic gate and gating it with set. This would ensure that the signal set or the signal setb will always take priority over the signal reset. Similarly, in some design implementations and in RTL coding styles, it may be a system requirement for reset to take priority over setb. In such a situation, it is recommended to convert the input inverter on the set signal into a logic gate and gating the signal off with the signal reset.

The input signal set is input to the inverter 611, and the output signal setb of the inverter 611 is input to the NAND gate 504 and the NAND gate 508. The input signal reset is input to the inverter 612, and the output signal of the inverter 612 is input to the NAND gate 503 and the NAND gate 507.

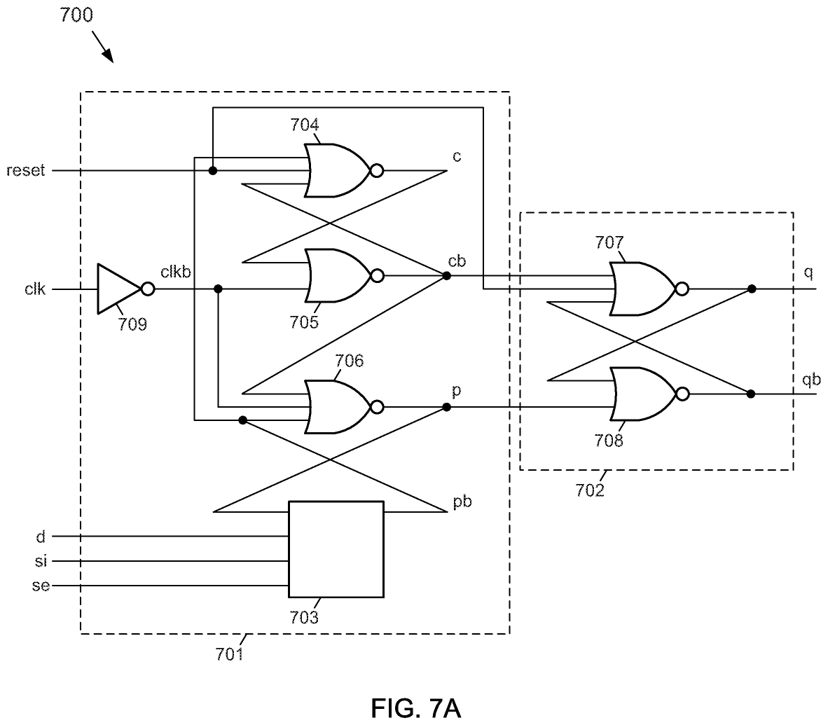

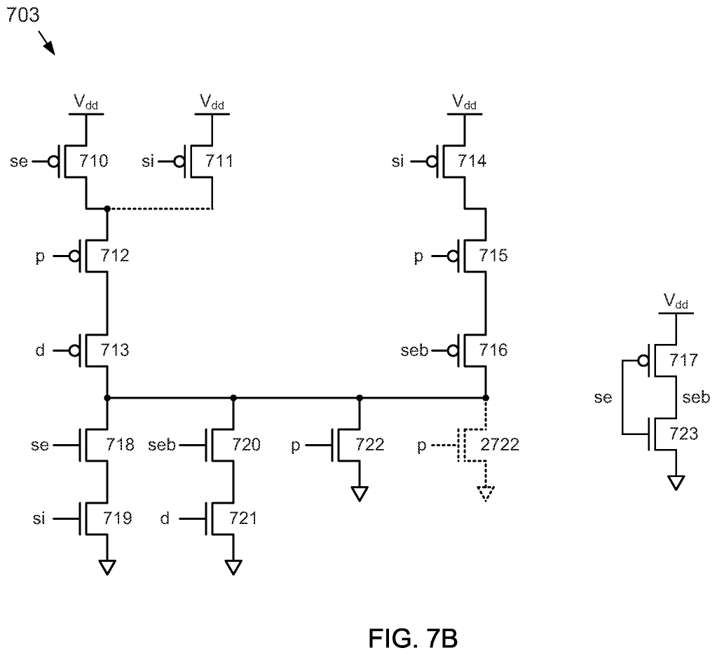

FIG. 7A is a schematic diagram of an example embodiment of a flip-flop 700 according to the subject matter disclosed herein. The flip-flop 700 may receive a data input signal d, a clock signal clk, a scan input signal si, a scan enable signal se, and an inverted reset signal resetb, and generates output signals q and qb. The flip-flop 700 may include a primary latch 701 and a secondary latch 702. The primary latch 701 may include an input gate circuit 703 and NOR gates 704-706, and the secondary latch 702 may include NOR gates 707 and 708.

The input gate circuit 703 may receive as inputs the data input signal d, an intermediate signal p, the scan input signal si and the scan enable signal se, and outputs an intermediate signal pb. The NOR gate 704 may receive as inputs the reset input signal reset, an intermediate signal pb, an intermediate signal cb, and outputs an intermediate signal c. The NOR gate 705 may receive as inputs an inverted clock signal clkb and the intermediate signal c, and outputs the intermediate signal cb. The NOR gate 706 may receive as inputs the inverted clock signal clkb, the intermediate signal pb and the intermediate signal cb, and outputs the intermediate signal p. An inverter 709 may receive the clock signal clk and outputs the inverted clock signal clkb.

The gate circuit 703 may perform the function of a scan multiplexer. For example, an inverting multiplexing gate between the input signal d and the scan input signal si that may be controlled by scan enable signal se and then combined with a subsequent NOR gate. There would be, however, an extra inversion on the data path in comparison to the input gate circuit 703. Merging the logic function into the input gate circuit 703 removes an inversion and may be implemented in minimal area. It may be useful to have both a configuration of the gate circuit 203 and a configuration of an inverting multiplexing gate with a subsequent NAND gate available to provide a full standard cell (stdcell) library that includes all families of flip-flops and all variations of flip-flops and signal polarities that may be used by designers,

The NOR gate 707 may receive as inputs the reset input signal reset, the intermediate signal cb and the output signal q, and outputs the output signal q. The NOR gate 708 may receive as inputs the output signal q and the intermediate signal p, and outputs the output signal qb.

FIG. 7B is a schematic diagram of the gate circuit 703 according to the subject matter disclosed herein. The gate circuit 703 may include PMOS transistors 710-716, and NMOS transistors 717-721.

The PMOS transistor 710 may have a first source/drain region coupled to a Vdd power supply voltage, a second source/drain region, and a gate terminal coupled to the input scan enable se. The PMOS transistor 711 may have a first source/drain region coupled to the Vdd power supply voltage, a second source/drain region coupled to the second source/drain region of the PMOS transistor 710, and a gate terminal coupled to the input scan signal si. It should be noted that the PMOS transistor 711 may not be needed if it is determined that there is no risk of a glitch occurring in the intermediate signal pb when the inverted signal seb changes and the scan input signal si equals the data input signal d. For most flip-flop circuits and designs disclosed herein, it is a good, very low risk assumption that that scan signal si and the scan enable signal se changing at the same time causes a glitch, so the input PMOS transistor 711 may often be omitted and replaced by a dummy or floating gate depending on the preference of a layout designer.

The PMOS transistor 712 may have a first source/drain region coupled to the second source/drain region of the PMOS transistor 710, a second source/drain region, and a gate terminal coupled to the intermediate signal p. The PMOS transistor 713 may have a first source/drain region coupled to the second source/drain region of the PMOS 712 transistor, a second source/drain region that outputs the intermediate signal pb, and a gate terminal coupled to the input data signal d. The PMOS transistor 714 may have a first source/drain region coupled to the Vdd power supply voltage, a second source/drain region, and a gate terminal coupled to the scan input signal si. The PMOS transistor 715 may have a first source/drain region coupled to the second source/drain region of the PMOS transistor 714, a second source/drain region, and a gate terminal coupled to the intermediate signal p. The PMOS transistor 716 may have a first source/drain region coupled to the second source/drain region of the PMOS transistor 615, a second source/drain region to output the intermediate signal pb, and a gate terminal coupled to a signal seb, which is an inverted signal of the scan enable signal se. The PMOS transistor 717 may have a first source/drain region coupled to the Vdd power supply voltage, a second source/drain region to output the signal seb, and a gate terminal coupled to the scan enable signal se.

The NMOS transistor 718 may include a first source/drain region that outputs the intermediate signal pb, a second source/drain region, and a gate terminal coupled to the scan enable signal se. The NMOS transistor 719 may include a first source/drain region coupled to the second source/drain region of the NMOS transistor 718, a second source/drain region, and a gate terminal coupled to the scan input signal si. The NMOS transistor 720 may include a first source/drain region that outputs the intermediate signal pb, a second source/drain region, and a gate terminal coupled to the signal seb. The NMOS transistor 721 may include a first source/drain region coupled to the second source/drain region of the NMOS transistor 720, a second source/drain region coupled to ground, and a gate terminal coupled to the input data signal d. The NMOS transistor 722 may include a first source/drain region to output the intermediate signal pb, a second source/drain region coupled to ground, and a gate terminal coupled to the intermediate signal p. The NMOS transistor 723 may include a first source/drain region that output the coupled to the second source/drain region of the NMOS transistor 720, a second source/drain region, and a gate terminal coupled to the scan input signal si. An NMOS transistor 2722 indicated by a dashed line may be connected in the same way as the NMOS transistor 722; however, the NMOS transistor 2722 may be redundant and, therefore, optional. Choice of using the NMOS transistor 2722 may be based on layout efficiency. The NMOS transistor 2722 may not be needed for circuit operation. To reduce capacitance and power inside the flip-flop 700, the NMOS transistor 2722 may be replaced with a dummy transistor.

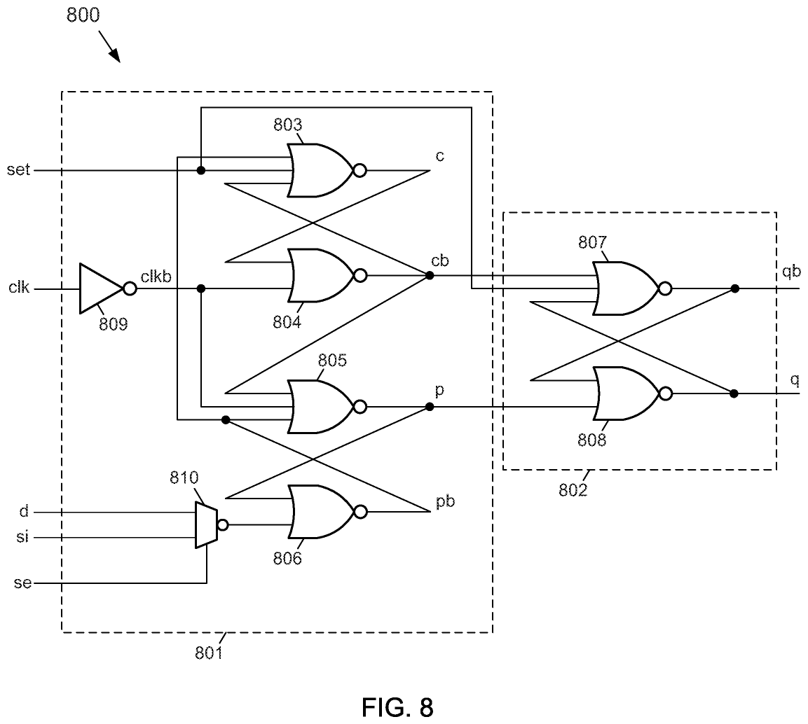

By flipping the polarity of the q and qb output signals, the flip-flop 700 may be configured to be used for a scan-in flip-flop having a set input signal. FIG. 8 is a schematic diagram of an example embodiment of a flip-flop 800 that includes an input signal set according to the subject matter disclosed herein. The flip-flop 800 may receive a data input signal d, a clock signal clk, a scan input signal si, a scan enable signal se, and a set signal set, and generates output signals q and qb.

Similar to the flip-flop 700, the flip-flop 800 may include a primary latch 801 and a secondary latch 802. The primary latch 801 may include NOR gates 803-806, and the secondary latch 802 may include NOR gates 807 and 808.

The NOR gate 803 may receive as inputs the input signal set, an intermediate signal pb, an intermediate signal cb, and outputs an intermediate signal c. The NOR gate 804 may receive as inputs an inverted clock signal clkb and the intermediate signal c, and outputs the intermediate signal cb. The NOR gate 805 may receive as inputs the inverted clock signal clkb, the intermediate signal pb and the intermediate signal cb, and outputs the intermediate signal p. The NOR gate 806 may receive as inputs either an inverted data input signal d or an inverted scan input signal si and the intermediate signal p, and outputs the intermediate signal pb. An inverter 809 may receive the clock signal clk and outputs the inverted clock signal clkb. A multiplexer 810 may receive the data input signal d and the scan input signal si, and outputs an inverted version of either signal depending on whether the flip-flop is in a normal mode (data input signal d) or a scan mode (scan input signal si). The multiplexer 810 may be controlled by the scan enable signal se.

The NOR gate 807 may receive as inputs the input signal set, the intermediate signal cb and the output signal q, and outputs the output signal qb. The NOR gate 808 may receive as inputs as inputs the output signal qb and the intermediate signal p, and outputs the output signal q.

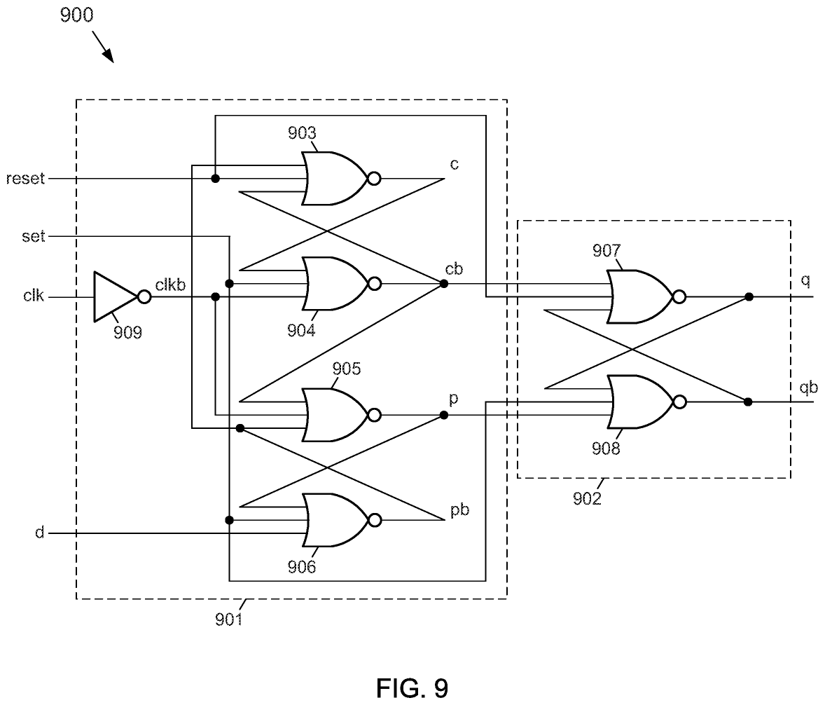

FIG. 9 is a schematic diagram of an example embodiment of a flip-flop 900 that includes an input signal set and an input signal reset according to the subject matter disclosed herein. The flip-flop 900 may receive a data input signal d, a clock signal clk, a set input signal set and a reset signal reset, and generates output signals q and qb. The flip-flop 900 may include a primary latch 901 and a secondary latch 902. The primary latch 901 may include NOR gates 903-906, and the secondary latch 802 may include NOR gates 907 and 908.

The NOR gate 903 may receive as inputs the input signal reset, an intermediate signal pb, an intermediate signal cb, and outputs an intermediate signal c. The NOR gate 904 may receive as inputs the input signal set, an inverted clock signal clkb and the intermediate signal c, and outputs the intermediate signal cb. The NOR gate 905 may receive as inputs the inverted clock signal clkb, the intermediate signal pb and the intermediate signal cb, and outputs the intermediate signal p. The NOR gate 906 may receive as inputs the data input signal d, the input signal set, and the intermediate signal p, and outputs the intermediate signal pb. An inverter 909 may receive the clock signal clk and outputs the inverted clock signal clkb.

The NOR gate 907 receives as inputs the input signal reset, the intermediate signal cb and the output signal qb, and outputs the output signal q. The NOR gate 908 may receive as inputs the input signal set, the output signal q and the intermediate signal p, and outputs the output signal qb.

Based on the details discussed herein, a family of flip-flops may be created for an actual standard cell (stdcell) library. Many of the flip-flops according to the subject matter disclosed herein save area one to two CPPs and also provided a reduced internal flip-flop clock power in comparison to conventional implementations. Table 1 summarizes some of the different families of flip-flops that may be created based on application needs.

TABLE 1
Different families of flip-flops that may be created.

| | | |
|---|---|---|
| 1 | With or Without Scan | |
| 2 | With or Without Asynchronous | |
| | Reset, or resetb instead | |
| 3 | With or Without Asynchronous | |
| | setb, or Set instead | |
| 4 | With both set and reset, and no | Asynchronous set/reset |
| | priority assigned or preferred flop | |
| | behavior when both asserted at the | |
| | same time | |
| 5 | With both set and reset, and Set has | Asynchronous set/reset |
| | priority | (Logic Gate is used to disable reset and |
| | | give priority to set) |
| 6 | With both set and reset, and Reset | Asynchronous set/reset |
| | has priority | (Logic Gate is used to disable set and |
| | | give priority to reset) |
| 7 | Posedge or Negedge flop | Inverter on clock is one way. However |
| | | use of Nor style flop is more efficient |
| | | for negedge flops |
| 8 | Two separate outputs such as for | If synthesis and PNR tools |
| | example q and q_b | characterization and timing, etc., can |
| | | handle it |
| 9 | Different drive strengths | Add an inverter on output qb to get a |
| | | strongly driven new output Q_out |
| 10 | Different Vt classes | |
| 11 | Clock enables | Modify logic gate to include one |
| | | additional input |
| 12 | Synchronous set/reset | Modify logic gate to include one |
| | | additional input |
| 13 | SDB, DDB, MDB or other | |
| | alternative type of diffusion break | |
| | technology used by different | |
| | foundries | |
| 14 | Swapping the gate order or | |
| | transistor order to optimize | |
| | Setup/Tcko/Hold/Area/power/circuit | |
| | robustness and internal margins - | |
| | provides alternative schematics and | |
| | layouts that may be optimal based | |
| | on different points of view. | |
| 15 | All possible combinations of above | |
| | embodiments | |

As will be recognized by those skilled in the art, the innovative concepts described herein can be modified and varied over a wide range of applications. Accordingly, the scope of claimed subject matter should not be limited to any of the specific exemplary teachings discussed above, but defined by the following claims.

What is claimed is:

1. A flip-flop, comprising:
a pair of primary latches and a secondary latch configured to output a first signal q and a second signal qb that is an inverse of the first signal q,
the pair of primary latches comprising:
a gate circuit configured to receive as inputs a data signal d, a first intermediate signal p, a first control signal si and a second control signal se, and to output a second intermediate signal pb;
a first logic gate configured to receive as an input the second intermediate signal pb, a third intermediate signal cb, and to output a fourth intermediate signal c;
a second logic gate configured to receive as inputs a clock signal clk and the fourth intermediate signal c, and to output the third intermediate signal cb; and
a third logic gate configured to receive as inputs the clock signal clk, the second intermediate signal pb and the third intermediate signal cb, and to output the first intermediate signal p; and
the secondary latch comprising:
a fourth logic gate configured to receive as inputs the third intermediate signal cb and the second signal qb, and to output the first signal q; and
a fifth logic gate configured to receive as inputs the first intermediate signal p and the first signal q, and to output the second signal qb.

2. The flip-flop of claim 1, wherein the second intermediate signal pb is high if:
the first intermediate signal p is low,
the data signal d and second control signal se are both low, or
the first control signal si is low and the second control signal se is high; and
wherein the second intermediate signal pb is low if:
the first intermediate signal p and data signal d are high and the second control signal se is low, or
the first control signal si, the second control signal se and the first intermediate signal p are high.

3. The flip-flop of claim 2, wherein the first, second, third, fourth and fifth logic gates are NAND gates.

4. The flip-flop of claim 3, wherein the gate circuit comprises
a first PMOS transistor comprising a first source/drain region coupled to a first power supply voltage, a second source/drain region, and a gate terminal coupled to the data signal d;
a second PMOS transistor comprising a first source/drain region coupled to the second source/drain region of the first PMOS transistor, a second source/drain region to output the second intermediate signal pb, and a gate terminal coupled to the second control signal se;
a third PMOS transistor comprising a first source/drain region coupled to the first power supply voltage, a second source/drain region, and a gate terminal coupled to the first control signal si;
a fourth PMOS transistor comprising a first source/drain region coupled to the second source/drain region of the third PMOS transistor, a second source/drain region to output the second intermediate signal pb, and a gate terminal coupled to a fifth intermediate signal seb; and
a fifth PMOS transistor comprising a first source/drain region coupled to the first power supply voltage, a second source/drain region to output the second intermediate signal pb, and a gate terminal coupled to the first intermediate signal p;
a first NMOS transistor comprising a first source/drain region to output the second intermediate signal pb, a second source/drain region, and a gate terminal coupled to the data signal d;
a second NMOS transistor comprising a first source/drain region coupled to the second source/drain region of the first NMOS transistor, a second source/drain region, and a gate terminal coupled to the first intermediate signal p;
a third NMOS transistor comprising a first source/drain region coupled to the second source/drain region of the second NMOS transistor, a second source/drain region coupled to a second power supply voltage, and a gate terminal coupled to the fifth intermediate signal seb;
a fourth NMOS transistor comprising a first source/drain region coupled to the second source/drain region of the second NMOS transistor, a second source/drain region coupled to the second power supply voltage, and a gate terminal coupled to the first control signal si;
a fifth NMOS transistor comprising a first source/drain region to output the second intermediate signal pb, a second source/drain region, and a gate terminal coupled to the second control signal se;
a sixth NMOS transistor comprising a first source/drain region coupled to the second source/drain region of the fifth NMOS transistor, a second source/drain region, and a gate terminal coupled to the first control signal si; and
a seventh NMOS transistor comprising a first source/drain region coupled to the second source/drain region of the sixth NMOS transistor, a second source/drain region coupled to the second power supply voltage, and a gate terminal coupled to the first intermediate signal p.

5. The flip-flop of claim 1, wherein the flip-flop is part of a standard-cell library of circuits.

6. The flip-flop of claim 1, wherein the flip-flop is arranged on a single diffusion break substrate or an alternative diffusion break substrate.

7. The flip-flop of claim 1, wherein the first, second, third, fourth and fifth logic gates are NOR gates.

8. The flip-flop of claim 7, wherein the second and third logic gates are configured to receive the clock signal clk as an inverted signal.

9. The flip-flop of claim 7, wherein the gate circuit comprises:
a first PMOS transistor comprising a first source/drain region coupled to a first power supply voltage, a second source/drain region, and a gate terminal coupled to the second control signal se;
a second PMOS transistor comprising a first source/drain region coupled to the second source/drain region of the first PMOS transistor, a second source/drain region, and a gate terminal coupled to the first intermediate signal p;
a third PMOS transistor comprising a first source/drain region coupled to the second source/drain region of the second PMOS transistor, a second source/drain region to output the second intermediate signal pb, and a gate terminal coupled to the data signal d;
a fourth PMOS transistor comprising a first source/drain region coupled to the first power supply voltage, a second source/drain region, and a gate terminal coupled to the first control signal si;
a fifth PMOS transistor comprising a first source/drain region coupled to the second source/drain region of the fourth PMOS transistor, a second source/drain region, and a gate terminal coupled to the first intermediate signal p; and
a sixth PMOS transistor comprising a first source/drain region coupled to the second source/drain region of the fifth PMOS transistor, a second source/drain region to output the second intermediate signal pb, and a gate terminal coupled to a fifth intermediate signal seb;
a first NMOS transistor comprising a first source/drain region to output the second intermediate signal pb, a second source/drain region, and a gate terminal coupled to the second control signal se;
a second NMOS transistor comprising a first source/drain region coupled to the second source/drain region of the first NMOS transistor, a second source/drain region coupled to a second power supply voltage, and a gate terminal coupled to the first control signal si;
a third NMOS transistor comprising a first source/drain region to output the second intermediate signal pb, a second source/drain region, and a gate terminal coupled to the fifth intermediate signal seb;
a fourth NMOS transistor comprising a first source/drain region coupled to the second source/drain region of the third NMOS transistor, a second source/drain region coupled to the second power supply voltage, and a gate terminal coupled to the data signal d; and
a fifth NMOS transistor comprising a first source/drain region to output the second intermediate signal pb, a second source/drain region coupled to the second power supply voltage, and a gate terminal coupled to the first intermediate signal p.

10. An apparatus, comprising:
a flip-flop arranged on a single diffusion break substrate or an alternative diffusion break substrate comprising a pair of primary latches and a secondary latch configured to output a first signal q and a second signal qb that is an inverse of the first signal q,
the pair of primary latches comprising:
a gate circuit configured to receive as inputs a data signal d, a first intermediate signal p, a first control signal si and a second control signal se, and to output a second intermediate signal pb;
a first logic gate configured to receive as an input the second intermediate signal pb, a third intermediate signal cb, and to output a fourth intermediate signal c;
a second logic gate configured to receive as inputs a clock signal clk and the fourth intermediate signal c, and to output the third intermediate signal cb; and
a third logic gate configured to receive as inputs the clock signal clk, the second intermediate signal p, the third intermediate signal cb, and to output the first intermediate signal p; and
the secondary latch comprising:
a fourth logic gate configured to receive as inputs the third intermediate signal cb and the second signal qb, and to output the first signal q; and
a fifth logic gate configured to receive as inputs the first intermediate signal p and the first signal q, and to output the second signal qb.

11. The flip-flop of claim 10, wherein the second intermediate signal pb is high if:
the first intermediate signal p is low,
the data signal d and second control signal se are both low, or
the first control signal si is low and the second control signal se is high; and
wherein the second intermediate signal pb is low if:
the first intermediate signal p and data signal d are high and the second control signal se is low, or
the first control signal si, the second control signal se and the first intermediate signal p are high.

12. The flip-flop of claim 11, wherein the first, second, third, fourth and fifth logic gates are NAND gates.

13. The flip-flop of claim 12, wherein the gate circuit comprises
a first PMOS transistor comprising a first source/drain region coupled to a first power supply voltage, a second source/drain region, and a gate terminal coupled to the data signal d;
a second PMOS transistor comprising a first source/drain region coupled to the second source/drain region of the first PMOS transistor, a second source/drain region to output the second intermediate signal pb, and a gate terminal coupled to the second control signal se;
a third PMOS transistor comprising a first source/drain region coupled to the first power supply voltage, a second source/drain region, and a gate terminal coupled to the first control signal si; and
a fourth PMOS transistor comprising a first source/drain region coupled to the second source/drain region of the third PMOS transistor, a second source/drain region to output the second intermediate signal pb, and a gate terminal coupled to a fifth intermediate signal seb; and
a fifth PMOS transistor comprising a first source/drain region coupled to the first power supply voltage, a second source/drain region to output the second intermediate signal pb, and a gate terminal coupled to the first intermediate signal p;
a first NMOS transistor comprising a first source/drain region to output the second intermediate signal pb, a second source/drain region, and a gate terminal coupled to the data signal d;
a second NMOS transistor comprising a first source/drain region coupled to the second source/drain region of the first NMOS transistor, a second source/drain region, and a gate terminal coupled to the first intermediate signal p;
a third NMOS transistor comprising a first source/drain region coupled to the second source/drain region of the second NMOS transistor, a second source/drain region coupled to a second power supply voltage, and a gate terminal coupled to the fifth intermediate signal seb;
a fourth NMOS transistor comprising a first source/drain region coupled to the second source/drain region of the second NMOS transistor, a second source/drain region coupled to the second power supply voltage, and a gate terminal coupled to the first control signal si;
a fifth NMOS transistor comprising a first source/drain region to output the second intermediate signal pb, a second source/drain region, and a gate terminal coupled to the second control signal se;
a sixth NMOS transistor comprising a first source/drain region coupled to the second source/drain region of the fifth NMOS transistor, a second source/drain region, and a gate terminal coupled to the first control signal si; and
a seventh NMOS transistor comprising a first source/drain region coupled to the second source/drain region of the sixth NMOS transistor, a second source/drain region coupled to the second power supply voltage, and a gate terminal coupled to the first intermediate signal p.

14. The flip-flop of claim 10, wherein the flip-flop is arranged on a single diffusion break substrate, a double diffusion break substrate, or an alternative diffusion break substrate.

15. The flip-flop of claim 10, wherein the first, second, third, fourth and fifth logic gates are NOR gates.

16. The flip-flop of claim 15, wherein the second and third logic gates are configured to receive the clock signal clk as an inverted signal.

17. The flip-flop of claim 16, wherein the gate circuit comprises:
a first PMOS transistor comprising a first source/drain region coupled to a first power supply voltage, a second source/drain region, and a gate terminal coupled to the second control signal se;
a second PMOS transistor comprising a first source/drain region coupled to the second source/drain region of the first PMOS transistor, a second source/drain region, and a gate terminal coupled to the first intermediate signal p;
a third PMOS transistor comprising a first source/drain region coupled to the second source/drain region of the second PMOS transistor, a second source/drain region to output the second intermediate signal pb, and a gate terminal coupled to the data signal d;
a fourth PMOS transistor comprising a first source/drain region coupled to the first power supply voltage, a second source/drain region, and a gate terminal coupled to the first control signal si;
a fifth PMOS transistor comprising a first source/drain region coupled to the second source/drain region of the fourth PMOS transistor, a second source/drain region, and a gate terminal coupled to the first intermediate signal p; and
a sixth PMOS transistor comprising a first source/drain region coupled to the second source/drain region of the fifth PMOS transistor, a second source/drain region to output the second intermediate signal pb, and a gate terminal coupled to a fifth intermediate signal seb;
a first NMOS transistor comprising a first source/drain region to output the second intermediate signal pb, a second source/drain region, and a gate terminal coupled to the second control signal se;
a second NMOS transistor comprising a first source/drain region coupled to the second source/drain region of the first NMOS transistor, a second source/drain region coupled to a second power supply voltage, and a gate terminal coupled to the first control signal si;
a third NMOS transistor comprising a first source/drain region to output the second intermediate signal pb, a second source/drain region, and a gate terminal coupled to the fifth intermediate signal seb;
a fourth NMOS transistor comprising a first source/drain region coupled to the second source/drain region of the third NMOS transistor, a second source/drain region coupled to the second power supply voltage, and a gate terminal coupled to the data signal d; and
a fifth NMOS transistor comprising a first source/drain region to output the second intermediate signal pb, a second source/drain region coupled to the second power supply voltage, and a gate terminal coupled to the first intermediate signal p.

18. The flip-flop of claim 17, wherein the flip-flop is arranged on a single diffusion break substrate, a double diffusion break substrate, or an alternative diffusion break substrate.

19. A flip-flop, comprising:
a gate circuit configured to receive as inputs a data input signal d, a first intermediate signal p, a first control signal si and a second control signal se, and to output a second intermediate signal pb;
a first logic gate configured to receive as an input the second intermediate signal pb, a third intermediate signal cb, and to output a fourth intermediate signal c;
a second logic gate configured to receive as inputs a clock signal clk and the fourth intermediate signal c, and to output the third intermediate signal cb;
a third logic gate configured to receive as inputs the clock signal clk, the second intermediate signal p, the third intermediate signal cb, and to output the first intermediate signal p;
a fourth logic gate configured to receive as inputs the third intermediate signal cb and a second signal qb, and to output a first signal q; and
a fifth logic gate configured to receive as inputs the first intermediate signal p and the first signal q, and to output the second signal qb.

20. The flip-flop of claim 19, wherein the first, second, third, fourth and fifth logic gates are NAND gates, or the first, second, third, fourth and fifth logic gates are NOR gates.
